(19) United States
(12) Patent Application Publication
(10) Pub. No.: US 2016/0126432 A1
(43) Pub. Date: May 5, 2016

(54) METHOD OF MANUFACTURING SEMICONDUCTOR LIGHT EMITTING DEVICE PACKAGE

(71) Applicant: SAMSUNG ELECTRONICS CO., LTD., Gyeonggi-do (KR)

(72) Inventors: Yong Min KWON, Suwon-si (KR); Jung Jin KIM, Suwon-si (KR); Hak Hwan KIM, Suwon-si (KR); Sung Jun IM, Suwon-si (KR)

(73) Assignee: SAMSUNG ELECTRONICS CO., LTD., Gyeonggi-do (KR)

(21) Appl. No.: 14/991,540

(22) Filed: Jan. 8, 2016

Related U.S. Application Data
(62) Division of application No. 14/297,199, filed on Jun. 5, 2014.

(30) Foreign Application Priority Data
Jun. 25, 2013 (KR) 10-2013-0073090

(51) Int. Cl. H01L 33/56; H01L 33/32; H01L 27/15; H01L 33/38; H01L 33/00; H01L 33/06; H01L 33/60

(52) U.S. Cl. CPC H01L 33/56; H01L 33/06; H01L 33/32; H01L 33/60; H01L 33/382; H01L 33/0095; H01L 27/153; H01L 2933/005; H01L 2933/0058; H01L 2933/0016; H01L 2933/0033

(57) ABSTRACT

A method of manufacturing a semiconductor light emitting device package includes providing a wafer and forming, on the wafer, a semiconductor laminate comprising a plurality of light emitting devices. Electrodes are formed in respective light emitting device regions of the semiconductor laminate. A curable resin is applied to a surface of the semiconductor laminate on which the electrodes are formed. A support structure is formed for supporting the semiconductor laminate by curing the curable resin. Through holes are formed in the support structure to expose the electrodes therethrough. Connection electrodes are formed in the support structure to be connected to the exposed electrodes.

### CROSS-REFERENCE TO RELATED APPLICATION

This is a Divisional of U.S. application Ser. No. 14/297,199 filed on Jun. 5, 2014, which claims priority from Korean Patent Application No. 10-2013-0073090 filed on Jun. 25, 2013, with the Korean Intellectual Property Office, the entire content of which is hereby incorporated by reference.

### TECHNICAL FIELD

The present disclosure relates to a method of manufacturing a semiconductor light emitting device package.

### BACKGROUND

Light emitting diodes (LEDs) are widely used as light sources, due to various advantages thereof, such as low power consumption, a high level of luminance, and the like. In particular, recently, light emitting devices have been employed in lighting devices and as backlight units in large liquid crystal display (LCD) devices. Light emitting devices are provided in the form of packages that can be easily installed in various devices such as lighting devices, or the like.

As the use of LEDs has extended into various fields, the size of light emitting device packages needs to be reduced to allow for a sufficient degree of freedom in the design of lighting devices for specific purposes. In addition, superior heat dissipation performance is a package condition significantly weighed in fields in which high output light emitting devices such as a general lighting device and a backlight for a large LCD device are required.

### SUMMARY

An aspect of the present disclosure provides a method of manufacturing a semiconductor light emitting device package allowing for improved semiconductor light emitting device characteristics, without an increase in manufacturing costs, through a simplified manufacturing process.

One aspect of the present disclosure relates to a method of manufacturing a semiconductor light emitting device package. The method includes providing a wafer and forming, on the wafer, a semiconductor laminate comprising a plurality of light emitting devices. Electrodes are formed in respective light emitting device regions of the semiconductor laminate. A curable resin is applied to a surface of the semiconductor laminate on which the electrodes are formed. A support structure is formed for supporting the semiconductor laminate by curing the curable resin. Through holes are formed in the support structure to expose the electrodes therethrough. Connection electrodes are formed in the support structure to be connected to the exposed electrodes.

The curable resin may include a high reflective powder.

The high reflective powder may include at least one selected from the group consisting of TiO₂, Al₂O₃, Nb₂O₅, Al₂O₃ and ZnO.

The curable resin applied to the surface of the semiconductor laminate may be a curable liquid resin.

The applying of the curable resin may include providing a semi-cured resin body for the support structure; and bonding the semi-cured resin body to the surface of the semiconductor laminate on which the electrodes are formed. The forming of the support structure may be performed by fully curing the semi-cured resin body.

The method may further include removing the wafer from the semiconductor laminate after the forming of the support structure.

The method may further include forming a wavelength conversion part on a surface of the semiconductor laminate from which the wafer is removed.

The method may further include forming an optical member on a surface of the semiconductor laminate from which the wafer is removed.

The surface of the semiconductor laminate on which the electrodes are formed may have a step portion.

Another aspect of the present disclosure encompasses a method of manufacturing a semiconductor light emitting device package. The method includes providing a wafer and forming, on the wafer, a semiconductor laminate comprising a plurality of light emitting devices. Electrodes are formed in respective light emitting device regions of the semiconductor laminate. A semi-cured resin body is provided for a support structure. The semi-cured resin body has connection electrodes formed by penetrating through regions of the semi-cured resin body corresponding to the electrodes. The semi-cured resin body is bonded to the semiconductor laminate while allowing the connection electrodes to be connected to the electrodes of the light emitting devices, respectively. A support structure is formed by fully curing the semi-cured resin body.

The semi-cured resin body may include a high reflective powder.

The providing of the semi-cured resin body may include forming a body for the support structure using a curable liquid resin; and forming the semi-cured resin body by curing the body for the support structure so as to be in a B-stage state.

The providing of the semi-cured resin body may include forming through holes in the through regions of the semi-cured resin body corresponding to the electrodes; and forming the connection electrodes in the through holes.

The connection electrodes formed in the semi-cured resin body may have bonding metal layers disposed in regions thereof connected to the electrodes.

The bonding of the semi-cured resin body to the semiconductor laminate may be performed by heating and compressing the semi-cured resin body and the semiconductor laminate.

Still another aspect of the present disclosure relates to a method of manufacturing a semiconductor light emitting device package. The method includes providing a wafer and forming, on the wafer, a semiconductor laminate comprising a plurality of light emitting devices. A portion of the semiconductor laminate is mesa-etched. Electrodes are formed on the mesa-etched portion of the semiconductor laminate. A curable resin is applied to a surface of the semiconductor laminate on which the electrodes are formed. A support structure is formed for supporting the semiconductor laminate by curing the curable resin. Through holes are formed in the support structure to expose the electrodes therethrough. Connection electrodes are formed in the support structure to be connected to the exposed electrodes.

The curable resin may include a reflective powder.

The reflective powder may include at least one selected from TiO₂, Al₂O₃, Nb₂O₅, Al₂O₃ and ZnO.

The curable resin applied to the surface of the semiconductor laminate may be a curable liquid resin.

The surface of the semiconductor laminate on which the electrodes are formed may have a step portion.

### BRIEF DESCRIPTION OF THE DRAWINGS

The above and other aspects, features and other advantages of the present inventive concept will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the present inventive concept. In the drawings, the thickness of layers and regions may be exaggerated for clarity.

FIGS. 1A through 1F are cross-sectional views illustrating a method of manufacturing a semiconductor light emitting device package according to an embodiment of the present inventive concept.

FIG. 2 is a schematic plan view of a wafer of FIG. 1A on which a semiconductor laminate is formed.

FIGS. 3A through 3E are cross-sectional views illustrating a method of manufacturing a semiconductor light emitting device package according to another embodiment of the present inventive concept.

FIG. 4 is a schematic cross-sectional view illustrating an example of a semiconductor light emitting device package that can be manufactured by a method of manufacturing a semiconductor light emitting device package according to an embodiment of the present inventive concept.

FIGS. 5A through 5F are cross-sectional views illustrating a method of manufacturing a semiconductor light emitting device package according to another embodiment of the present inventive concept.

FIGS. 6 and 7 are cross-sectional views illustrating examples of semiconductor light emitting devices applicable to embodiments of the present inventive concept.

FIGS. 8A through 8D are cross-sectional views illustrating a method of manufacturing a wafer-level packaging substrate according to another embodiment of the present inventive concept.

FIG. 9 is a cross-sectional view of a wafer having a semiconductor laminate formed thereon according to another embodiment of the present inventive concept.

FIGS. 10A through 10C are cross-sectional views illustrating a method of manufacturing a semiconductor light emitting device package using the packaging substrate of MG. 8D and the wafer of FIG. 9.

FIGS. 11 and 12 illustrate examples of a backlight unit to which a semiconductor light emitting device package according to an embodiment of the present inventive concept is applied.

FIG. 13 illustrates an example of a lighting device to which a semiconductor light emitting device package according to an embodiment of the present inventive concept is applied.

FIG. 14 illustrates an example of a headlamp to which a semiconductor light emitting device package according to an embodiment of the present inventive concept is applied.

### DETAILED DESCRIPTION OF THE EMBODIMENTS

Embodiments of the present inventive concept will now be described in detail with reference to the accompanying drawings.

The inventive concept may, however, be exemplified in many different forms and should not be construed as being limited to the specific embodiments set forth herein. Rather, these embodiments are provided so that this disclosure will be thorough and complete, and will fully convey the scope of the inventive concept to those skilled in the art.

In the drawings, the shapes and dimensions of elements may be exaggerated for clarity, and the same reference numerals will be used throughout to designate the same or like elements.

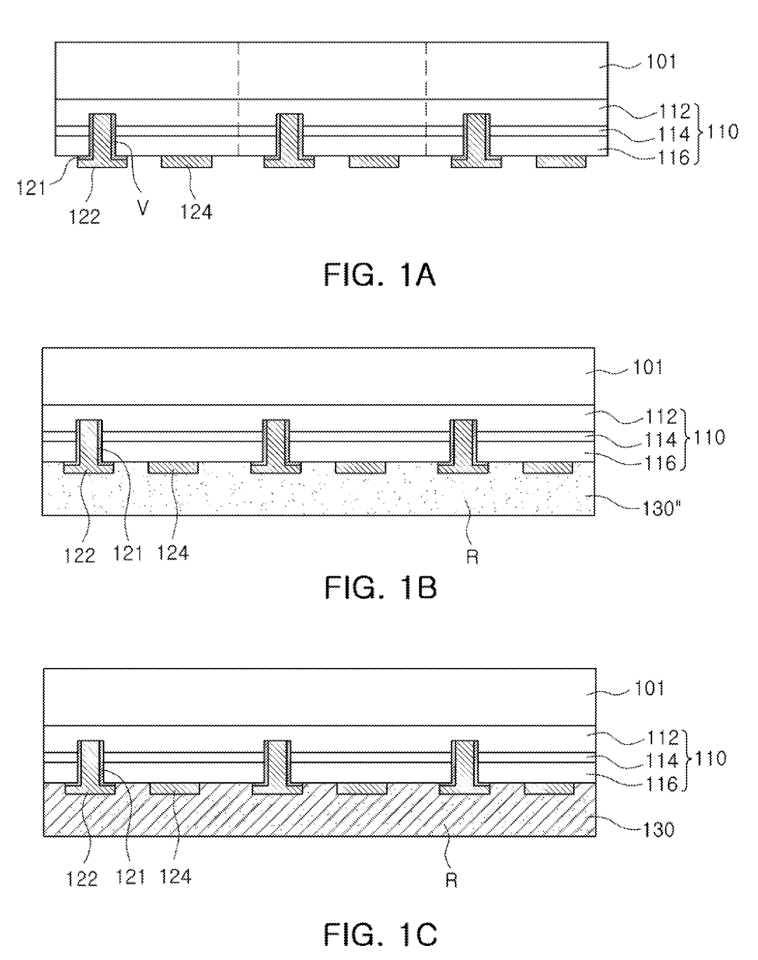

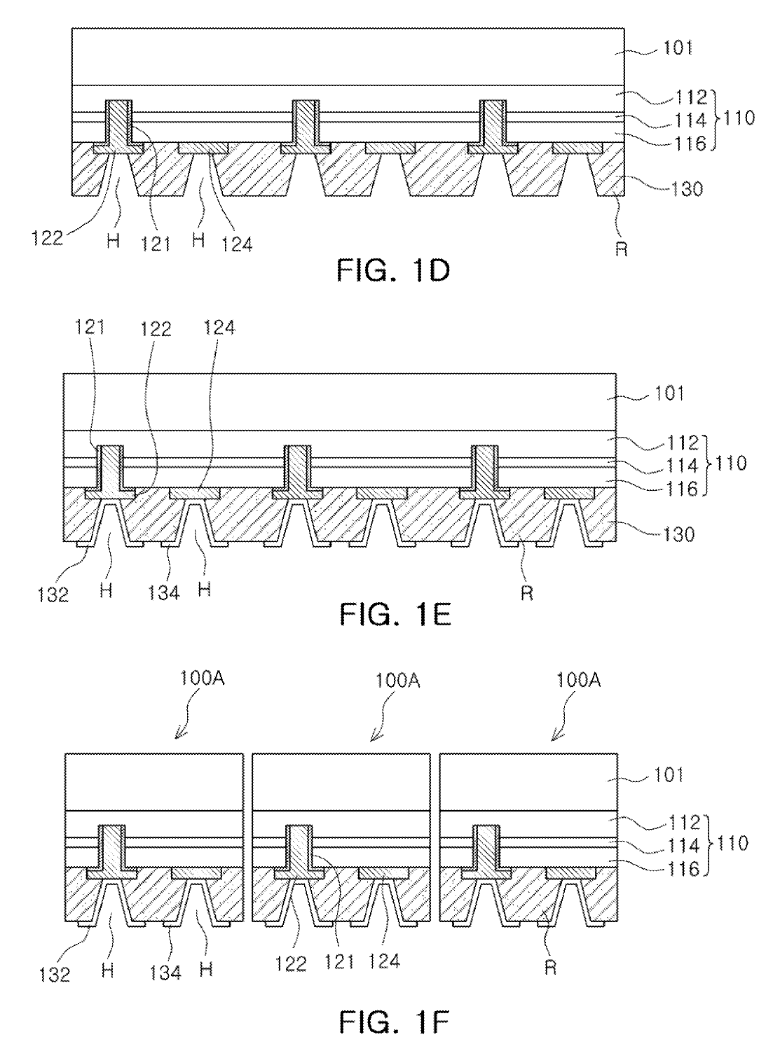

FIGS. 1A through 1F are cross-sectional views illustrating a method of manufacturing a semiconductor light emitting device package according to an embodiment of the present inventive concept.

As illustrated in FIG. 1A, the manufacturing method according to an embodiment of the present inventive concept may start with providing a wafer 101 having a semiconductor laminate 110 formed thereon.

The semiconductor laminate 110 comprising a plurality of light emitting devices may include epitaxial layers formed on the wafer 101. The semiconductor laminate 110 may include a first conductivity-type semiconductor layer 112, an active layer 114 and a second conductivity-type semiconductor layer 116.

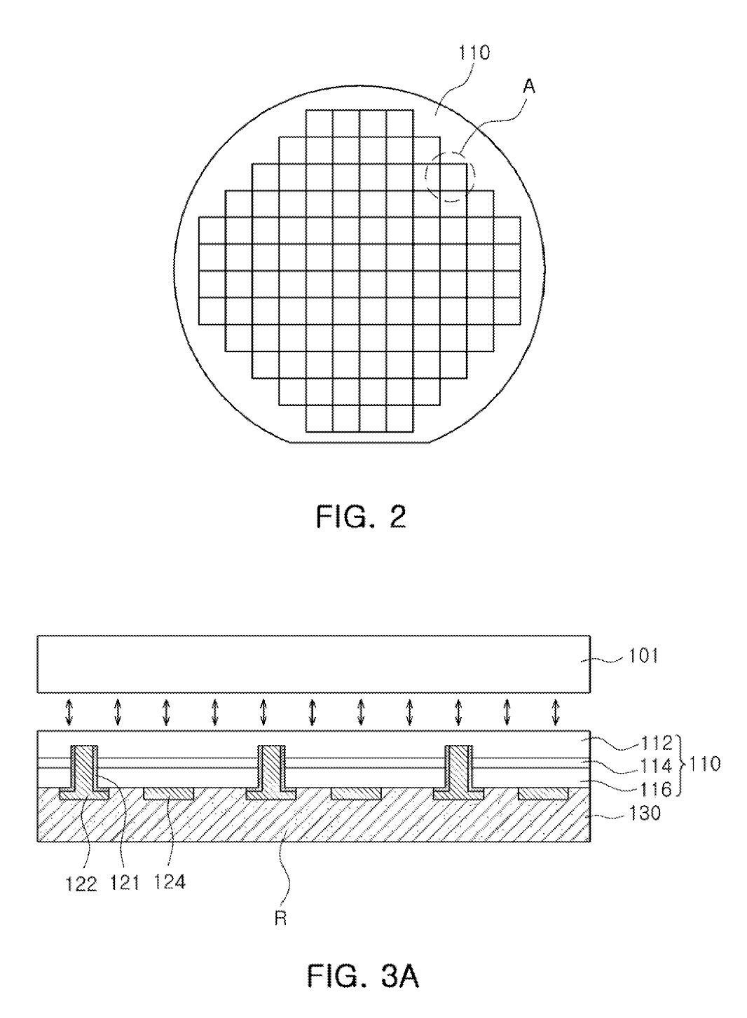

FIG. 2 is a schematic plan view of the wafer 101 of FIG. 1A on which the semiconductor laminate 110 is formed. As illustrated in FIG. 2, the semiconductor laminate 110 for each light emitting device A may be formed on the wafer 101. Hereinafter, FIGS. 1A through 1F illustrate enlarged cross-sectional views of three light emitting devices A in order to enhance comprehension of the inventive concept.

The wafer 101 may be an insulating substrate, a conductive substrate, or a semiconductor substrate as necessary. For example, the wafer 101 may be formed of sapphire, SiC, Si, MgAl₂O₄, MgO, LiAlO₂, LiGaO₂, and GaN.

The semiconductor laminate 110 may be formed of group-III nitride semiconductors. For example, the first and second conductivity-type semiconductor layers 112 and 116 may be formed of a nitride single crystal having a composition of AlₓIn_{y}Ga_{1-x-y}N (0≦x≦1, 0≦y≦1, 0≦x+y≦1). The material of the semiconductor layers is not limited thereto, and AlGaInP-based semiconductors or AlGaAs-based semiconductors may be used.

The first and second conductivity-type semiconductor layers 112 and 116 may be formed of semiconductors doped with n-type and p-type impurities, respectively. Alternatively, the first and second conductivity-type semiconductor layers 112 and 116 may be formed of semiconductors doped with p-type and n-type impurities, respectively.

The active layer 114 disposed between the first and second conductivity-type semiconductor layers 112 and 116 may have a multi quantum well (MQW) structure in which quantum well layers and quantum barrier layers are alternately stacked. For example, in the case of nitride semiconductors, a GaN/InGaN structure may be used. Alternatively, a single quantum well (SQW) structure may also be used.

As illustrated in FIG. 1A, first and second electrodes 122 and 124 may be disposed to be connected to the first and second conductivity-type semiconductor layers 112 and 116, respectively. The first and second electrodes 122 and 124 may be provided in respective light emitting device regions.

In an embodiment of the present inventive concept, the first electrode 122 may be formed to have a via v connected to the first conductivity-type semiconductor layer 112. An insulating film 121 may be formed on an internal surface of the via v and a portion of a surface of the semiconductor laminate 110, thereby preventing the first electrode 122 from undesirably contacting the active layer 114 and the second conductivity-type semiconductor layer 116. In an embodiment of the present inventive concept, the pair of first and second electrodes 122 and 124 is illustrated as being formed on the same surface of the semiconductor laminate 110 for every light emitting device region. However, the electrodes may be differently disposed according to chip structures. An electrode having a polarity may be formed on one surface of a single light emitting device region and an electrode having an opposite polarity may be formed on the other surface thereof, or two or more electrodes having one polarity may be provided.

The first and second electrodes 122 and 124 may include silver (Ag), nickel (Ni), aluminum (Al), rhodium (Rh), palladium (Pd), iridium (Jr), ruthenium (Ru), magnesium (Mg), zinc (Zn), platinum (Pt), gold (Au), or the like, and may have a structure including two or more layers such as Ni/Ag, Zn/Ag, Ni/Al, Zn/Al, Pd/Ag, Pd/Al, Ir/Ag, Ir/Au, Pt/Ag, Pt/Al, Ni/Ag/Pt, or the like, without being limited thereto.

Next, as illustrated in FIG. 1B, a curable resin 130″ may be applied to the surface of the semiconductor laminate 110 on which the first and second electrodes 122 and 124 are formed.

The curable resin 130″ may include a high reflective powder R. Here, the high reflective powder R may be a high reflective metal powder or a high reflective ceramic powder. The high reflective ceramic powder may include at least one selected from TiO₂, Al₂O₃, Nb₂O₅, Al₂O₃ and ZnO. Alternatively, the high reflective metal powder including Al, Ag or the like may be used. The high reflective metal powder may be included in an appropriate amount allowing for a support structure to be maintained as an insulating structure, thereby increasing reflectivity of the support structure itself. Therefore, the support structure may have a high level of reflectivity, unlike a silicon (Si) substrate that has conventionally been used, and the support structure may improve light extraction efficiency of a final semiconductor light emitting device package.

The curable resin 130″ may be a curable liquid resin that is an uncured resin having liquidity before curing and is capable of being cured when energy such as heat, ultraviolet rays, or the like is applied thereto. The curable resin 130″ may be applied using various methods. For example, the curable resin 130″ may be applied by spin-coating, screen printing, inkjet printing, dispensing or the like to thereby form a resin body having a predetermined thickness.

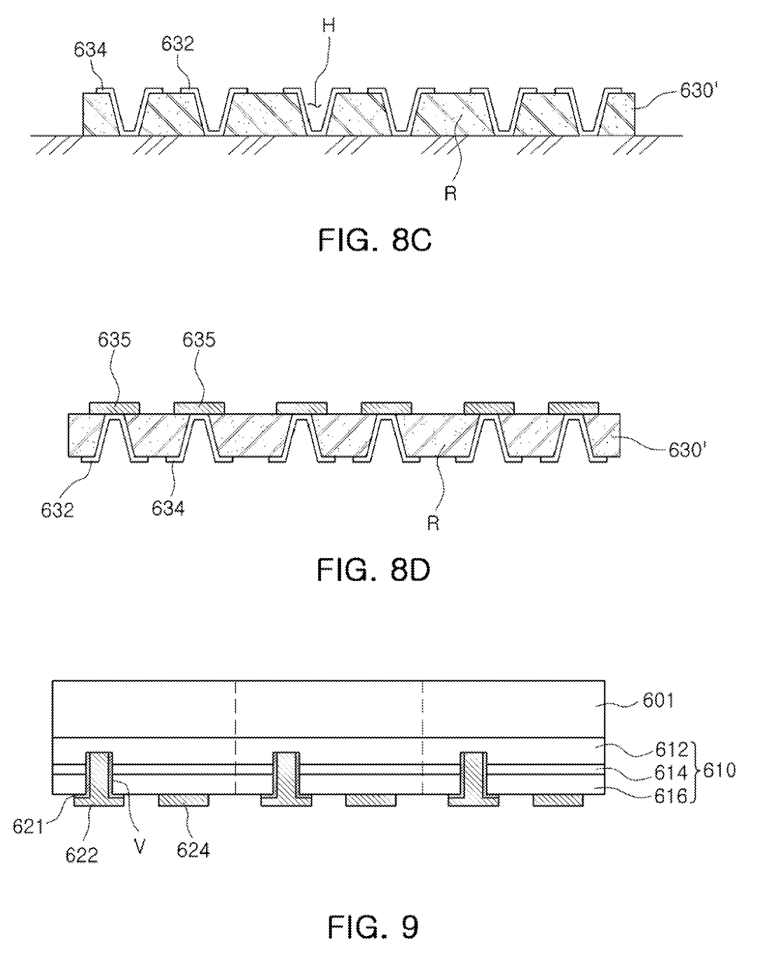

Alternatively, a semi-cured resin body may be separately prepared as a support structure, and the semi-cured resin body may be bonded to the surface of the semiconductor laminate on which the electrodes are formed. The terms “semi-curing” and “semi-cured” used throughout the specification refer to a state in which a material is not fully cured, but is cured to the extent of having ease of handling and machinability. For example, in a general curing reaction, a fully cured resin may be understood as being in a C-stage state, while a semi-cured resin may be understood as being in a B-stage state. Such a semi-cured resin body may be compressed at an appropriate temperature, such that it may be bonded to the surface of the semiconductor laminate as illustrated in FIG. 1B. This process will be clearly understood with reference to FIGS. 8A and 8B.

The curable resin 130″ may be an electrical insulating resin in order to facilitate separation between connection electrodes connected to an external circuit. For example, the curable resin 130″ usable in an embodiment of the present inventive concept may be a silicone resin, an epoxy resin or a mixture thereof, but is not limited thereto.

Then, as illustrated in FIG. 1C, the curable resin 130″ may be cured to form a support structure 130 for supporting the semiconductor laminate 110.

As described above, the curable resin 130″ may be cured by applying energy (e.g., heat or ultraviolet rays) thereto. The cured resin body may have machinability and mechanical stability, such that it may be used as the support structure 130.

In particular, the curable resin 130″ in a liquid state before curing in the process of FIG. 1B may be directly applied to the surface of the semiconductor laminate 110 and then cured, thereby forming the support structure 130 bonded to the surface of the semiconductor laminate 110. Therefore, a bonding material for bonding the support structure 130 may not be used and an additional bonding process may not be required, whereby the support structure may be provided through a simplified process.

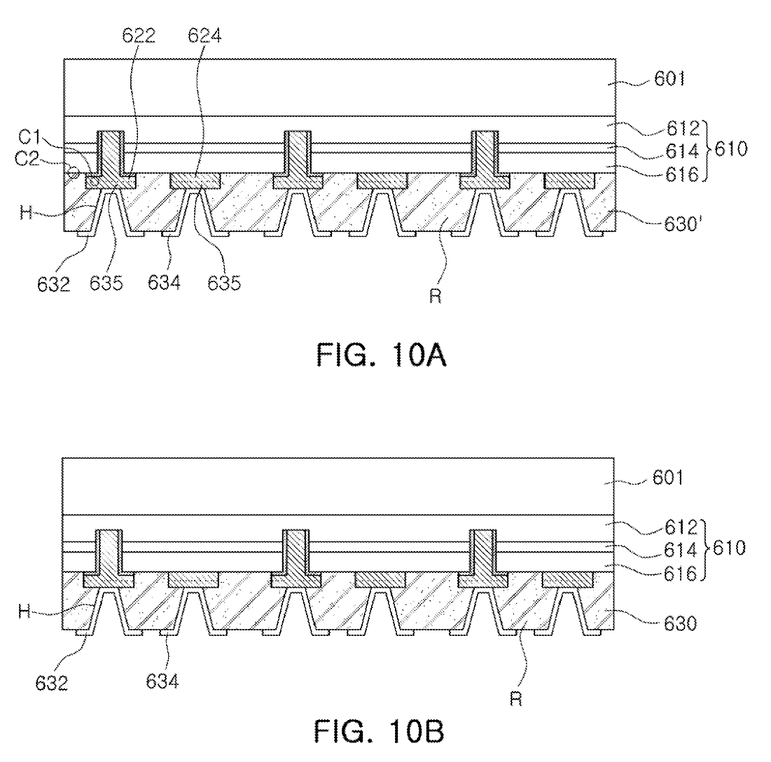

Likewise, when the semi-cured resin body is employed in the process of FIG. 1B, the semi-cured resin body may receive energy applied thereto to be fully cured, whereby the support structure 130 having machinability and mechanical stability may be obtained. Here, the full-curing process may be understood with reference to FIG. 10B.

In an embodiment of the present inventive concept, the support structure 130 may be formed of a resin having a predetermined level of reflectivity. As described above, the support structure 130 may be formed by mixing a transparent resin such as a silicone resin, an epoxy resin or a mixture thereof with the high reflective powder R.

The high reflective powder R may be a high reflective metal powder or a high reflective ceramic powder. The high reflective ceramic powder may include at least one selected from TiO₂, Al₂O₃, Nb₂O₅, Al₂O₃ and ZnO. Alternatively, the high reflective metal powder including Al, Ag, or the like may be used. The high reflective metal powder may be included in an appropriate amount allowing for the support structure to be maintained as an insulating structure, thereby increasing reflectivity of the support structure itself.

Therefore, when the support structure having a high level of reflectivity is used, light extraction efficiency of a final semiconductor light emitting device package may be improved.

Then, referring to FIGS. 1D and 1E, first and second connection electrodes 132 and 134 may be formed in the support structure 130 so as to be connected to an external circuit.

As illustrated in FIG. 1D, through holes H may be formed in the support structure 130 to allow the first and second electrodes 122 and 124 to be exposed therethrough.

Here, the through holes H may be formed by reactive ion etching (RIE), laser-mechanical drilling or the like. The through holes H may be formed in regions in which the connection electrodes are to be formed, such that they allow the first and second electrodes 122 and 124 to be exposed.

Then, as illustrated in FIG. 1E, the first and second connection electrodes 132 and 134 may be formed in the support structure 130 so as to be connected to portions of the first and second electrodes exposed through the through holes H, respectively. The first and second connection electrodes 132 and 134 may extend from the exposed portions of the first and second electrodes 122 and 124 to portions of a lower surface of the support structure 130 along the through holes H, so that they may be connected to the external circuit on the lower surface of the support structure 130. The first and second connection electrodes 132 and 134 may be formed by forming a seed layer using Ni, Cr, or the like, and plating the seed layer with an electrode material such as Au or the like.

In an embodiment of the present inventive concept, the support structure 130 may be formed on the semiconductor laminate 110 beforehand, and then the connection electrodes 132 and 134 may be formed.

The resultant structure of FIG. 1E may be cut into individual light emitting devices, whereby semiconductor light emitting device packages 100A (see FIG. 1F) may be manufactured. As illustrated in FIG. 1F, since the support structure 130 is provided using the curable resin, an additional bonding process may be omitted, and the support structure 130 may be bonded to the surface of the semiconductor laminate 110 without the use of a bonding material. In addition, since the support structure 130 is formed of a high reflective resin, light generated in the active layer 114 of the semiconductor laminate 110 may be effectively extracted in a desired direction.

In the embodiment illustrated in FIGS. 1A-1F, the forming of the support structure using the curable resin was mainly described. A process for adding specific functions to a semiconductor light emitting device may be additionally performed, as will be described in the following.

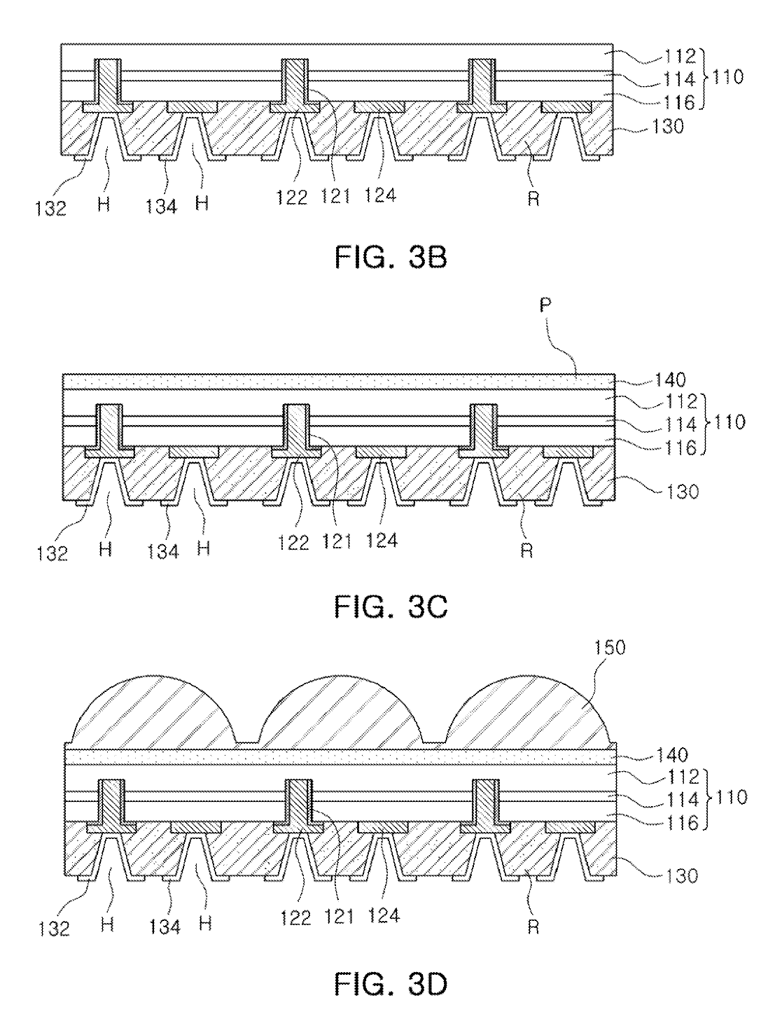

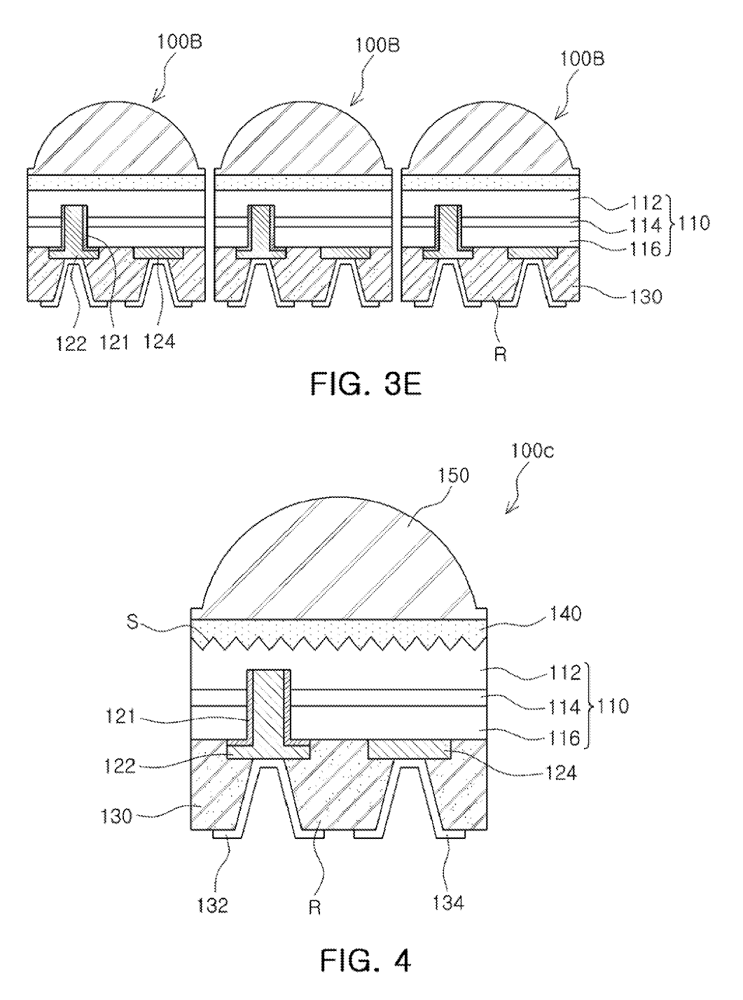

FIGS. 3A through 3E are cross-sectional views illustrating a method of manufacturing a semiconductor light emitting device package according to another embodiment of the present inventive concept. In an embodiment of the present inventive concept, the manufacturing method may include a process of separating a wafer (a growth substrate) and a process of employing a wavelength conversion part and an optical member.

The structure of FIG. 3A may be understood as being the same structure as that of FIG. 1C, except that the wafer 101 used as the growth substrate may be separated from the semiconductor laminate 110 as illustrated in FIG. 3A, before the connection electrodes are formed. The separating process may be performed by laser lift off (LLO), but is not limited thereto. Alternatively, the wafer may be removed by mechanical or chemical etching.

Then, as illustrated in FIG. 3B, the connection electrodes 132 and 134 may be formed in the support structure 130 to be connected to an external circuit. This process may the same as the process illustrated in FIGS. 1D and 1E. That is, the through holes H may be formed in the support structure 130 to allow the first and second electrodes 122 and 124 to be exposed, and then the first and second connection electrodes 132 and 134 may be formed in the support structure 130 to be connected to the portions of the first and second electrodes 122 and 124 exposed through the through holes H.

Then, as illustrated in FIG. 3C, a wavelength conversion part 140 may be formed on a surface of the semiconductor laminate 110 from which the wafer 101 is removed.

The wavelength conversion part 140 may be formed as a resin layer containing a wavelength conversion material P such as phosphors or quantum dots. The wavelength conversion material P in the wavelength conversion part 140 may be excited by light emitted from the active layer 114, thereby converting at least a portion of the light into light having a different wavelength. The wavelength conversion material P may include two or more materials providing light having different wavelengths. The light converted by the wavelength conversion part 140 and the light emitted from the active layer 114 may be combined to produce white light.

Then, as illustrated in FIG. 3D, an optical member 150 such as a lens or the like may be provided on the wavelength conversion part 140. In an embodiment of the present inventive concept, a convex lens may be exemplified as the optical member, but various structures capable of changing an angle of beam spread may be used therefor. Alternatively, the optical member 150 may be directly provided on the surface of the semiconductor laminate 100 from which the wafer has been removed, without the forming of the wavelength conversion part 140, as necessary.

The resultant structure of FIG. 3D may be cut into individual light emitting devices, whereby semiconductor light emitting device packages 100B (see FIG. 3E) may be manufactured. As illustrated in FIG. 3E, the support structure 130 having a high level of reflectivity may be employed to effectively extract light generated in the active layer 114 of the semiconductor laminate 110 in a desired direction, and after the removal of the wafer, the wavelength conversion part 140 and/or the optical member 150 such as a lens or the like may be employed to implement desired optical characteristics.

In an embodiment of the present inventive concept, after the support structure 130 is formed, the wafer 101 may be removed from the semiconductor laminate 110 before the connection electrodes 132 and 134 are formed. Alternatively, the removal of the wafer may be performed at any time after the support structure 130 is formed. For example, the removal of the wafer may be performed after the connection electrodes 132 and 134 are formed or after the through holes H for the connection electrodes 132 and 134 are formed.

A method of manufacturing a semiconductor light emitting device package according to an embodiment of the present inventive concept may allow for semiconductor light emitting device packages to have various structures. For example, a semiconductor light emitting device package 100C illustrated in FIG. 4 may have a structure similar to that of the semiconductor light emitting device package 100B illustrated in FIG. 3E, but may have depressions and protrusions S formed in the surface of the semiconductor laminate 110 on which the wavelength conversion part 140 is formed. The depressions and protrusions S may improve light extraction efficiency by effectively extracting light from the semiconductor laminate 110. The depressions and protrusions S may be formed by etching the surface of the semiconductor laminate 110 after the wafer 101 is removed or while the wafer 101 is being removed.

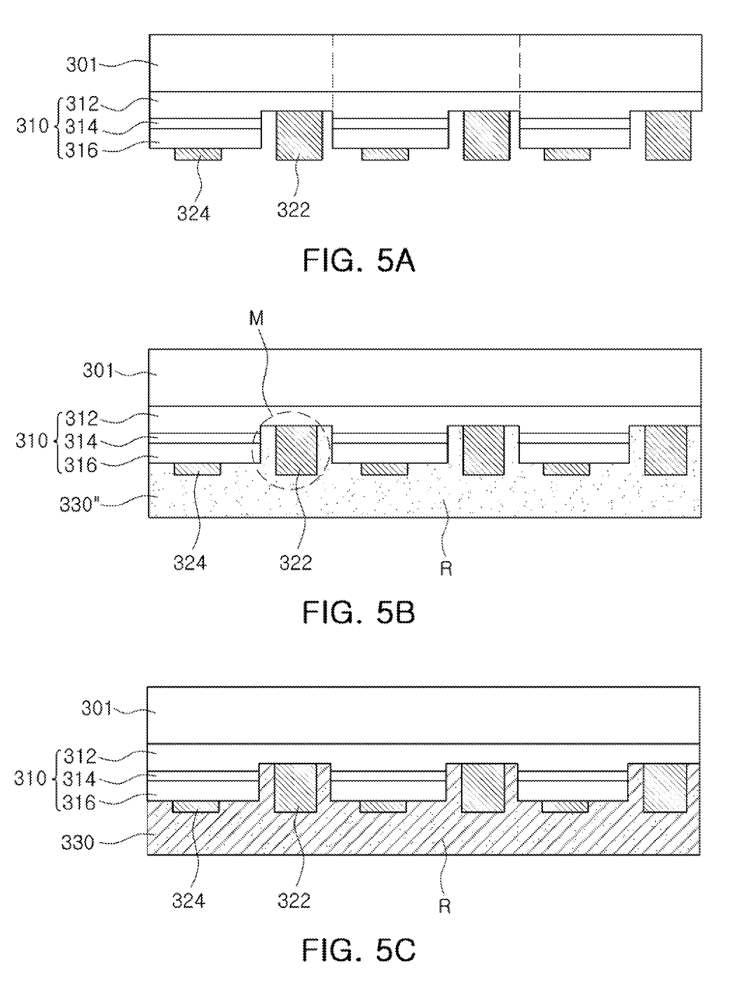

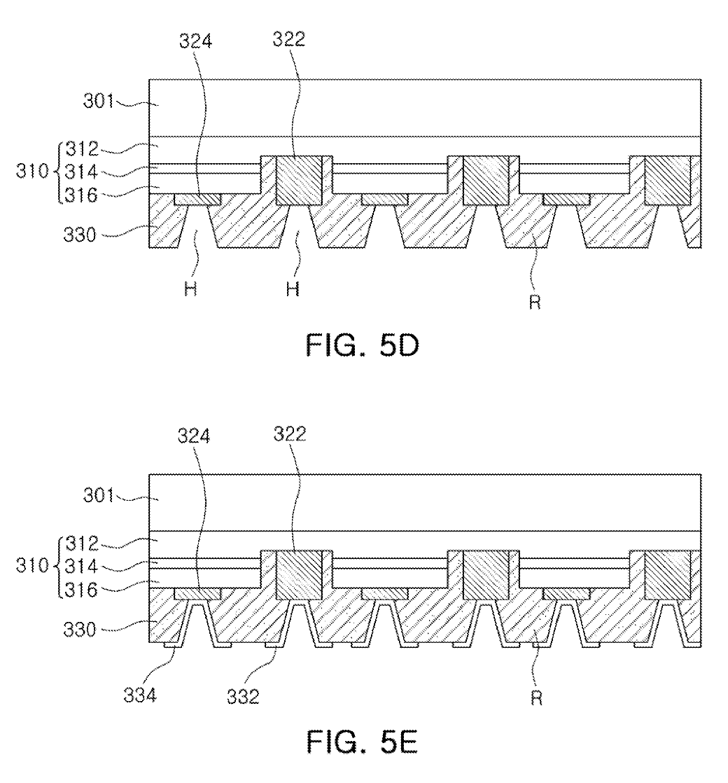

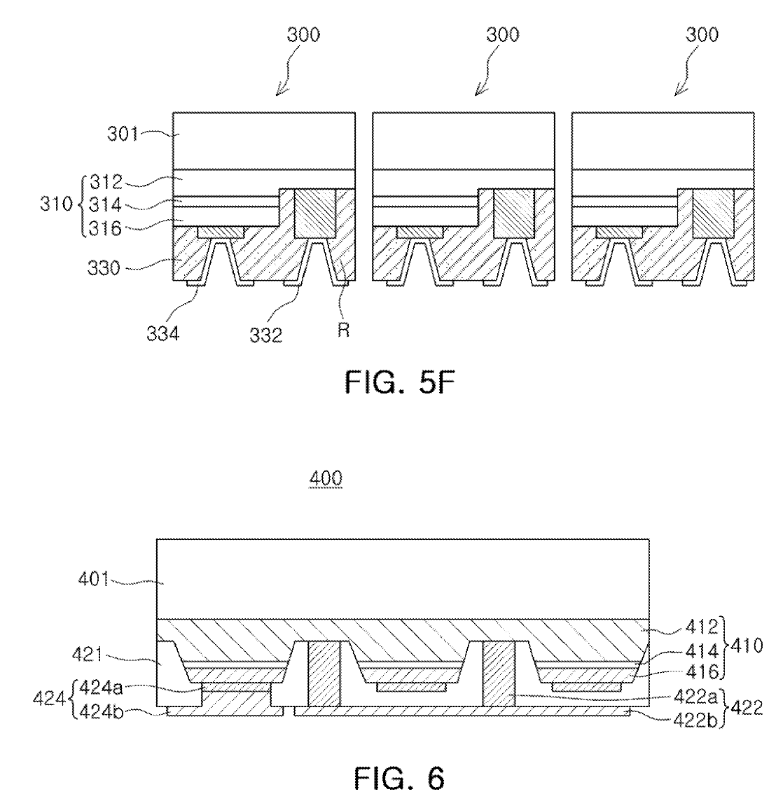

Since the element having liquidity or flexibility such as the curable resin or the semi-cured resin body is applied to the surface of the semiconductor laminate in the above-described embodiments, a contact area therebetween may be stably secured in a case in which a step portion is formed on the surface of the semiconductor laminate, as compared with a substrate formed of a material having a certain degree of hardness. FIGS. 5A through 5F are cross-sectional views illustrating a method of manufacturing a semiconductor light emitting device package having a mesa-etched structure according to another embodiment of the present inventive concept.

As illustrated in FIG. 5A, the manufacturing method according to an embodiment of the present inventive concept may start with providing a wafer 301 having a semiconductor laminate 310 formed thereon.

The semiconductor laminate 310 to be formed as a plurality of light emitting devices may include epitaxial layers formed on the wafer 310. The semiconductor laminate 310 may include a first conductivity-type semiconductor layer 312, an active layer 314 and a second conductivity-type semiconductor layer 316.

As illustrated in FIG. 5A, first and second electrodes 322 and 324 may be provided in respective light emitting device regions, so that they may be connected to the first and second conductivity-type semiconductor layers 312 and 316, respectively.

In addition, a portion of the first conductivity-type semiconductor layer 312 may be mesa-etched to form the first electrode 322 on the mesa-etched portion. The mesa-etching process may be performed to remove portions of the second conductivity-type semiconductor layer 316 and the active layer 314.

Then, as illustrated in FIG. 5B, a curable resin 330″ may be applied to a surface of the semiconductor laminate 310 on which the first and second electrodes 322 and 324 are formed.

The curable resin 330″ may contain a high reflective powder R. Here, the high reflective powder R may be a high reflective metal powder or a high reflective ceramic powder. The high reflective ceramic powder may include at least one selected from TiO₂, Al₂O₃, Nb₂O₅, Al₂O₃ and ZnO. Alternatively, the high reflective metal powder including Al, Ag or the like, may be used. The high reflective metal powder may be included in an appropriate amount allowing for a support structure to be maintained as an insulating structure, thereby increasing reflectivity of the support structure itself. Therefore, the support structure may have a high level of reflectivity, unlike a silicon (Si) substrate that has conventionally been used, and the support structure may improve light extraction efficiency of a final semiconductor light emitting device package.

Since the curable resin 330″ has liquidity before curing, or has a high degree of flexibility even when being used as the semi-cured resin body, the curable resin 330″ may be effectively bonded to a surface of the semiconductor laminate on which the first and second electrodes are formed. In particular, when the curable resin 330″ is provided to an uneven mesa-etched surface, for example, a surface having step portions, of the semiconductor laminate 310, sufficient areas of the semiconductor laminate 310 and the curable resin 330″ may be bonded to one another, including the mesa-etched regions M (see FIG. 5B), so that a high degree of bonding strength may be secured.

Then, as illustrated in FIG. 5C, the curable resin 330″ may be cured to form a support structure 330 for supporting the semiconductor laminate 310.

As described above, the curable resin 330″ may be fully cured by applying energy (e.g., heat or ultraviolet rays) thereto. The cured resin body may have machinability and mechanical stability, such that it may be used as the support structure 330.

Then, as illustrated in FIG. 5D, through holes H may be formed in the support structure 330 to allow the first and second electrodes 322 and 324 to be exposed therethrough. As illustrated in FIG. 5E, first and second connection electrodes 332 and 334 may be formed in the support structure 330 so as to be connected to portions of the first and second electrodes exposed through the through holes H, respectively.

The first and second connection electrodes 332 and 334 may extend from the exposed portions of the first and second electrodes 322 and 324 to portions of a lower surface of the support structure 330 along the through holes H, so that they may be connected to an external circuit on the lower surface of the support structure 330.

The resultant structure of FIG. 5E may be cut into individual light emitting devices, whereby semiconductor light emitting device packages 300 (see FIG. 5F) may be manufactured. As illustrated in FIG. 5F, since the support structure 330 is provided using the curable resin, an additional bonding process may be omitted, and the support structure 330 may be bonded to the surface of the semiconductor laminate 310 without the use of a bonding material. In addition, since the support structure 330 is formed of a high reflective resin, light generated in the active layer 314 of the semiconductor laminate 310 may be effectively extracted in a desired direction.

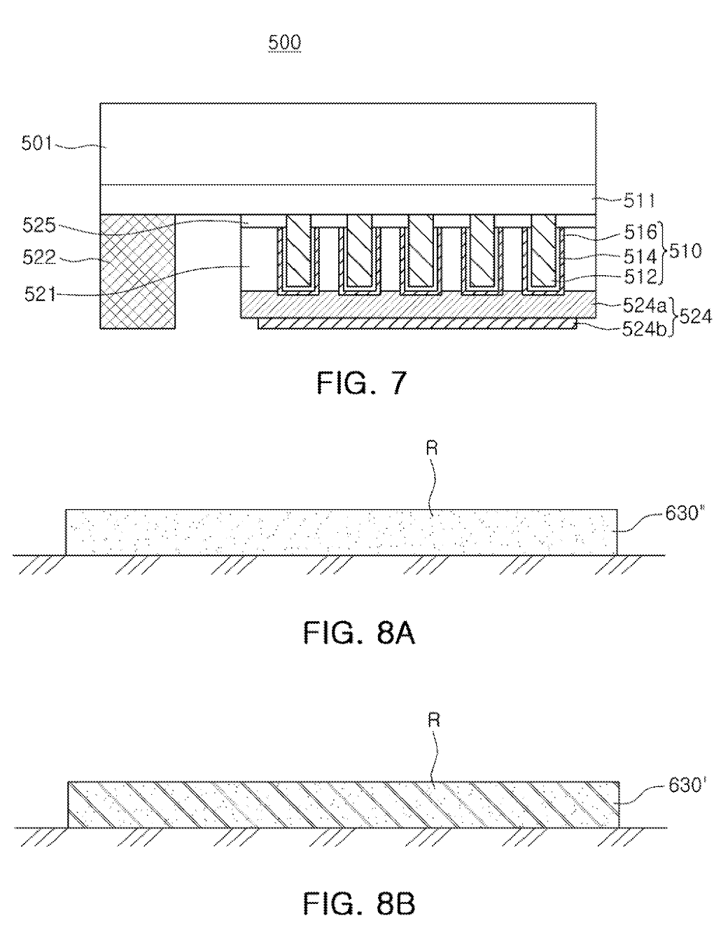

Semiconductor light emitting devices having various structures may be applicable to embodiments of the inventive concept. FIGS. 6 and 7 are cross-sectional views illustrating examples of semiconductor light emitting devices applicable to embodiments of the inventive concept.

A semiconductor light emitting device 400 illustrated in FIG. 6 may include a substrate 401 and a semiconductor laminate 410 formed on the substrate 401. The semiconductor laminate 410 may include a first conductivity-type semiconductor layer 412, an active layer 414 and a second conductivity-type semiconductor layer 416.

The semiconductor light emitting device 400 may include first and second electrodes 422 and 424 connected to the first and second conductivity-type semiconductor layers 412 and 416, respectively. The first electrode 422 may include conductive vias 422a and an electrode extension portion 422b connected to the conductive vias 422a. The conductive vias 422a may penetrate through the second conductivity-type semiconductor layer 416 and the active layer 414 to be connected to the first conductivity-type semiconductor layer 412. The conductive vias 422a may be enclosed by an insulating layer 421 to be electrically separated from the active layer 414 and the second conductivity-type semiconductor layer 416. The conductive vias 422a may be positioned in etched regions of the semiconductor laminate 410. In order to reduce contact resistance, the conductive vias 422a may be appropriately adjusted in terms of number, shape, pitch, and areas thereof in contact with the first conductivity-type semiconductor layer 412. In addition, the conductive vias 422a may be arranged in rows and columns to thereby improve current flow. The second electrode 424 may include an ohmic contact layer 424a formed on the second conductivity-type semiconductor layer 416 and an electrode extension portion 424b. For example, the ohmic contact layer 424a may be formed between the second conductivity-type semiconductor layer 416 and the electrode extension portion 424b.

A semiconductor light emitting device 500 illustrated in FIG. 7 may include a substrate 501, a first conductivity-type semiconductor base layer 511 formed on the substrate 501, and a plurality of light emitting nano-structures 510 formed on the first conductivity-type semiconductor base layer 511.

The semiconductor light emitting device 500 may further include an insulating layer 525 and a filler 521. The light emitting nano-structure 510 may include a first conductivity-type semiconductor core 512, and an active layer 514 and a second conductivity-type semiconductor layer 516 that are sequentially grown on a surface of the core as cell-layers.

In an embodiment of the present inventive concept, the light emitting nano-structure 510 may have a core-shell structure, but the structure thereof is not limited thereto. The light emitting nano-structure 510 may have different structures such as a pyramid structure or the like. The first conductivity-type semiconductor base layer 511 may provide a growth surface for the light emitting nano-structures 510. The insulating layer 525 may provide an open region for the growth of the light emitting nano-structure 510 and may be formed of a dielectric material such as SiO₂, SiNₓ, or the like. The filler 521 may structurally stabilize the light emitting nano-structures 510, and may serve to allow light to be transmitted therethrough or may reflect light. When the filler 521 includes a light-transmissive material, the filler 521 may be formed of a transparent material such as SiO₂, SiNx, an elastic resin, silicone, an epoxy resin, a polymer, or plastic. When the filler 521 includes a reflective material, the filler 521 may be formed by mixing a polymer material such as polyphthalamide (PPA), or the like, with a high reflective metal powder or a high reflective ceramic powder. The high reflective ceramic powder may include at least one selected from TiO₂, Al₂O₃, Nb₂O₅, Al₂O₃ and ZnO. Alternatively, the high reflective metal powder including Al, Ag, or the like may be used.

First and second electrodes 522 and 524 may be formed in a lower portion of the light emitting device 500. The first electrode 522 may be positioned on an exposed surface of the first conductivity-type semiconductor base layer 511, and the second electrode 524 may include an ohmic contact layer 524a formed below the light emitting nano-structures 510 and the filler 521 and an electrode extension portion 524b. Alternatively, the ohmic-contact layer 524a and the electrode extension portion 524b may be integrally formed.

In embodiments of the present inventive concept, after the curable liquid resin or the semi-cured resin body is applied to the semiconductor laminate, the connection electrodes may be formed. However, this process may be performed in different manners. For example, the connection electrodes may be formed before the semi-cured resin body is applied to the semiconductor laminate. This is illustrated with reference to FIGS. 8A through 8D and FIGS. 10A through 10C.

FIGS. 8A through 8D are cross-sectional views illustrating a method of manufacturing a semi-cured resin body to be used as a packaging substrate according to an embodiment of the present inventive concept.

As illustrated in FIG. 8A, a curable resin may be used to manufacture a resin body 630″ for a support structure. The curable resin may be a curable liquid resin that is an uncured resin having liquidity before curing and is capable of being cured when energy such as heat, ultraviolet rays or the like is applied thereto.

The curable resin may be applied by various methods. For example, the curable resin may be applied by spin-coating, screen printing, inkjet printing, dispensing or the like to thereby form the resin body having a predetermined thickness.

The resin body 630″ may be formed of an electrical insulating resin in order to facilitate separation between connection electrodes connected to an external circuit. For example, the curable resin may be a silicone resin, an epoxy resin or a mixture thereof, but is not limited thereto. The resin body 630″ may include a high reflective powder R. The high reflective powder R may be provided in a state of being dispersed in the curable liquid resin before being formed as the resin body. A high reflective metal powder or a high reflective ceramic powder may be used. The high reflective ceramic powder may include at least one selected from TiO₂, Al₂O₃, Nb₂O₅, Al₂O₃ and ZnO. Alternatively, the high reflective metal powder including Al, Ag, or the like may be used. The high reflective metal powder may be included in an appropriate amount allowing for the resin body to be maintained as an insulating structure, thereby increasing reflectivity of the resin body itself.

Then, as illustrated in FIG. 8B, the resin body 630″ to be formed as the support structure may be partially cured, thereby forming the semi-cured resin body 630′.

The semi-cured resin body 630′ may be obtained by curing the resin body 630″ in a B-stage state. As described above, the semi-cured resin body 630′ may be partially cured, but not fully cured, which is usually referred to as a B-stage state. Since the semi-cured resin body 630′ is cured to the extent of having ease of handling and machinability, through holes or connection electrodes may be formed therein. The semi-cured resin body 630′ may be compressed at an appropriate temperature to thereby be directly bonded to a surface of a semiconductor laminate without a bonding material.

Then, as illustrated in FIG. 8C, through holes H may be formed in regions of the semi-cured resin body 630′ corresponding to electrodes of individual light emitting devices. The first and second connection electrodes 632 and 634 may be formed in the through holes H.

The through holes H may be formed by reactive ion etching (RIE), laser-mechanical drilling or the like. The through holes H may be formed in the regions in which the connection electrodes are to be formed. The first and second connection electrodes 632 and 634 may extend from one opening portions of the through holes H to the other opening portions of the semi-cured resin body 630′ along the through holes H, so that they may be connected to the external circuit on the lower surface of the semi-cured resin body 630′. The first and second connection electrodes 632 and 634 may be formed by forming a seed layer using Ni, Cr or the like and plating the seed layer with an electrode material such as Au or the like.

Then, as illustrated in FIG. 8D, bonding metal layers 635 may be formed on portions of the first and second connection electrodes 632 and 634 formed in the semi-cured resin body 630′ to be connected to the electrodes of the individual light emitting devices.

The bonding metal layers 635 may be provided to secure stable connections between the previously formed connection electrodes and the electrodes of the light emitting devices. The bonding metal layers 635 may be formed of Au or a eutectic metal containing Au.

FIG. 9 is a cross-sectional view of a wafer having a semiconductor laminate formed thereon according to another embodiment of the present inventive concept.

A wafer 601 of FIG. 9 may include a semiconductor laminate 610 formed on a surface thereof, similar to the wafer 101 of FIG. 1. The semiconductor laminate 610 may include a first conductivity-type semiconductor layer 612, an active layer 614 and a second conductivity-type semiconductor layer 616.

The wafer 601 may be an insulating substrate, a conductive substrate, or a semiconductor substrate, as necessary. For example, the wafer 601 may be formed of sapphire, SiC, Si, MgAl₂O₄, MgO, LiAlO₂, LiGaO₂, and GaN. The semiconductor laminate 610 may be formed of group-III nitride semiconductors. For example, the first and second conductivity-type semiconductor layers 612 and 616 may be formed of a nitride single crystal having a composition of AlₓIn_{y}Ga_{1-x-y}N (0≦x≦1, 0≦y≦1, 0≦x+y≦1). The active layer 614 disposed between the first and second conductivity-type semiconductor layers 612 and 616 may have a multi quantum well (MQW) structure in which quantum well layers and quantum barrier layers are alternately stacked. For example, in the case of nitride semiconductors, a GaN/InGaN structure may be used. Alternatively, a single quantum well (SQW) structure may also be used.

As illustrated in FIG. 9, first and second electrodes 622 and 624 may be disposed to be connected to the first and second conductivity-type semiconductor layers 612 and 616, respectively. The first and second electrodes 622 and 624 may be provided in individual light emitting device regions. In an embodiment of the present inventive concept, the first electrode 622 may be formed to have a via v connected to the first conductivity-type semiconductor layer 612. An insulating film 621 may be formed on an internal surface of the via v and a portion of a surface of the semiconductor laminate 610, thereby preventing the first electrode 622 from undesirably contacting the active layer 614 and the second conductivity-type semiconductor layer 616.

FIGS. 10A through 10C are cross-sectional views illustrating a method of manufacturing a semiconductor light emitting device package using the packaging substrate of FIG. 8D and the wafer of FIG. 9.

As illustrated in FIG. 10A, the semiconductor laminate 610 and the semi-cured resin body 630′ may be bonded to one another while allowing the first and second connection electrodes 632 and 634 to be connected to the first and second electrodes 622 and 624 of the light emitting device.

Such a bonding process may be performed by heating and compressing the semiconductor laminate 610 and the semi-cured resin body 630′. Since the semi-cured resin body 630′ is not fully cured, the semi-cured resin body 630′ may be effectively bonded to the surface of the semiconductor laminate 610 by applying a predetermined amount of pressure thereto at a predetermined temperature (see the bonding portion “C2” in FIG. 10A).

In addition, even when the first and second electrodes 622 and 624 directly contact the first and second connection electrodes 632 and 634, they may be difficult to be bonded to one another, and thus, as illustrated in FIG. 8D, the bonding metal layers 635 may be formed on portions of the connection electrodes 632 and 634 to be bonded to the electrodes 622 and 624 of the semiconductor light emitting device (see the bonding portion “C1” in FIG. 10A). The bonding metal layers 635 may be formed of a conductive material allowing for electrode bonding at a low temperature that does not disadvantageously affect the semi-cured resin body). For example, the bonding metal layers may be formed of Au or a eutectic metal containing Au.

As illustrated in FIG. 10B, the semi-cured resin body 630′ may be fully cured to form a support structure 630. The semi-cured resin body 630′ may be fully cured in a state of contacting the surface of the semiconductor laminate 610 when energy is applied thereto, thereby forming the stable support structure 630 including the first and second connection electrodes 632 and 634 formed therein.

In an embodiment of the present inventive concept, the bonding process and the full-curing process are separately performed. However, the bonding process illustrated in FIG. 10A and the full-curing process sequentially performed as illustrated in FIG. 10B may be performed as a substantially single process.

The resultant structure illustrated in FIG. 10C may be cut into individual light emitting devices, whereby semiconductor light emitting device packages 600A may be manufactured. As illustrated in FIG. 10B, since the support structure 630 is provided using the semi-cured resin body, an additional bonding process may be omitted, and the support structure 630 may be bonded to the surface of the semiconductor laminate 610 without the use of a bonding material. In addition, since the support structure 630 is formed of a high reflective resin, light generated in the active layer 614 of the semiconductor laminate 610 may be effectively extracted in a desired direction.

A process for adding specific functions to the semiconductor light emitting device may be additionally applied to an embodiment of the present inventive concept. For example, depressions and protrusions (S of FIG. 4) may be employed in addition to the processes illustrated in FIGS. 3A through 3E.

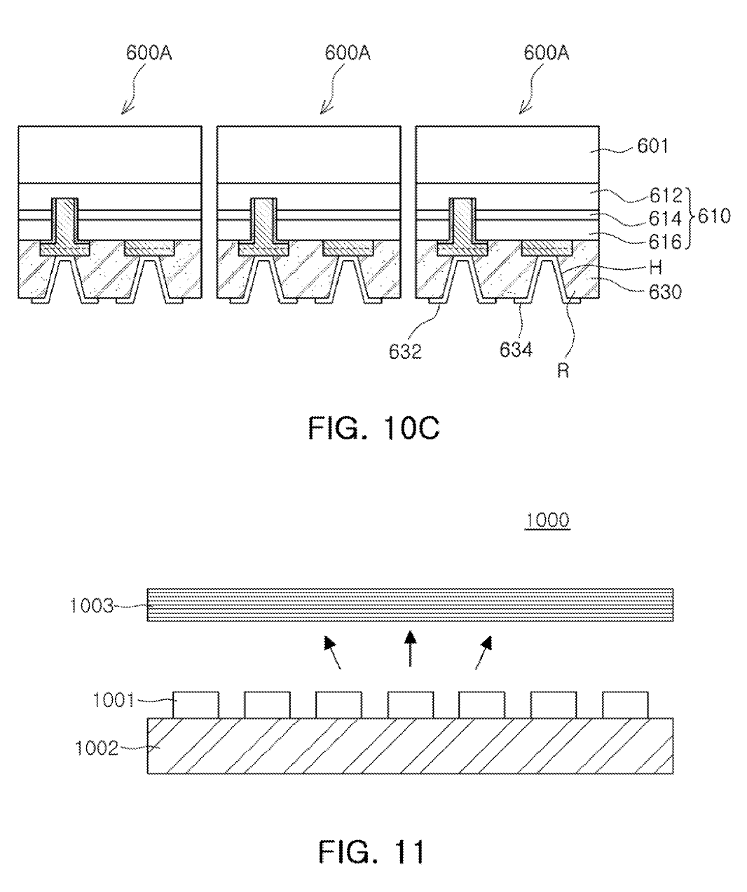

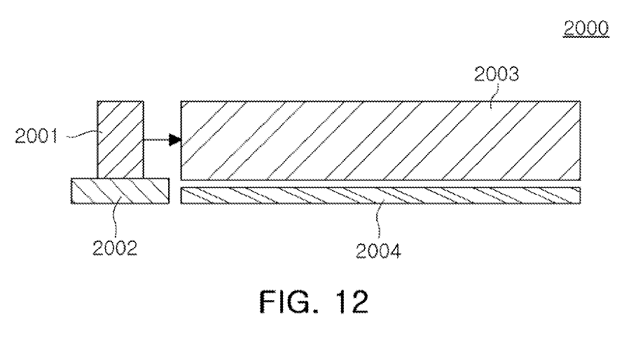

FIGS. 11 and 12 illustrate examples of a backlight unit to which a semiconductor light emitting device package according to an embodiment of the present inventive concept is applied.

With reference to FIG. 11, a backlight unit 1000 may include at least one light source 1001 mounted on a substrate 1002 and at least one optical sheet 1003 disposed thereabove. The light source 1001 may be a semiconductor light emitting device package having the above-described structure or a structure similar thereto. For example, the first and second connection electrodes 132 and 134 of the semiconductor light emitting device package 100C of FIG. 4 may be connected to an electrode pattern of the substrate 1002.

The light source 1001 in the backlight unit 1000 of FIG. 11 emits light toward a liquid crystal display (LCD) device disposed thereabove, whereas a light source 2001 mounted on a substrate 2002 in a backlight unit 2000 of FIG. 12 emits light laterally and the light is incident to a light guide plate 2003 such that the backlight unit 2000 may serve as a surface light source. The light travelling to the light guide plate 2003 may be emitted upwardly and a reflective layer 2004 may be formed below a lower surface of the light guide plate 2003 in order to improve light extraction efficiency.

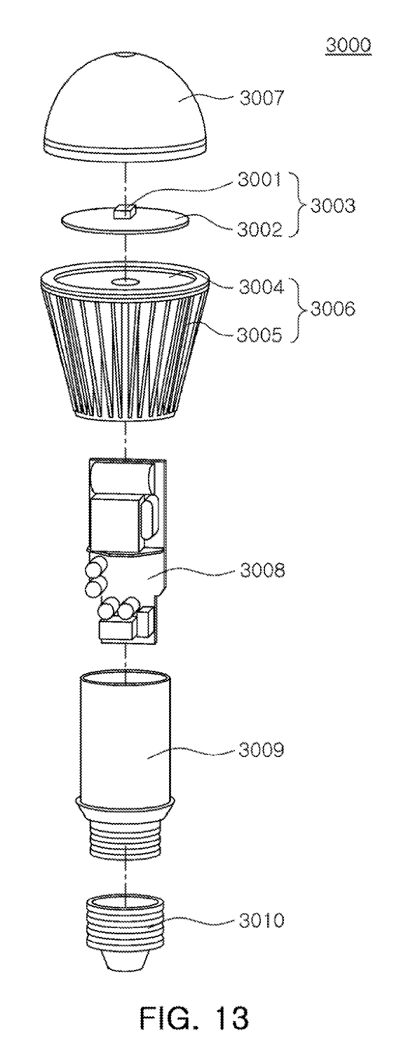

FIG. 13 is an exploded perspective view illustrating an example of a lighting device to which a semiconductor light emitting device package according to an embodiment of the present inventive concept is applied.

A lighting device 3000 of FIG. 13 is exemplified as a bulb-type lamp, and includes a light emitting module 3003, a driving unit 3008 and an external connector unit 3010.

In addition, exterior structures, such as external and internal housings 3006 and 3009, a cover unit 3007, and the like, may be additionally included. The light emitting module 3003 may include a light source 3001 having the above-described semiconductor light emitting device package structure or a structure similar thereto and a circuit board 3002 having the light source 3001 mounted thereon. For example, the first and second connection electrodes 132 and 134 of the semiconductor light emitting device package 100C of FIG. 4 may be connected to an electrode pattern of the circuit board 3002. In an embodiment of the present inventive concept, a single light source 3001 may be mounted on the circuit board 3002. However, as necessary, a plurality of light sources may be mounted thereon.

The external housing 3006 may serve as a heat radiating unit, and may include a heat sink plate 3004 in direct contact with the light emitting module 3003 to thereby improve heat dissipation, and a heat radiating fin 3005 surrounding a lateral surface of the lighting device 3000. In addition, the cover unit 3007 may be disposed above the light emitting module 3003 and have a convex lens shape. The driving unit 3008 may be disposed inside the internal housing 3009 and connected to the external connector unit 3010 such as a socket structure to receive power from an external power source. In addition, the driving unit 3008 may convert the received power into power appropriate for driving the semiconductor light emitting device 3001 of the light emitting module 3003 and supply the converted power thereto. For example, the driving unit 3008 may be provided as an AC-DC converter, a rectifying circuit part, or the like.

In addition, although not shown, the lighting device 3000 may further include a communications module.

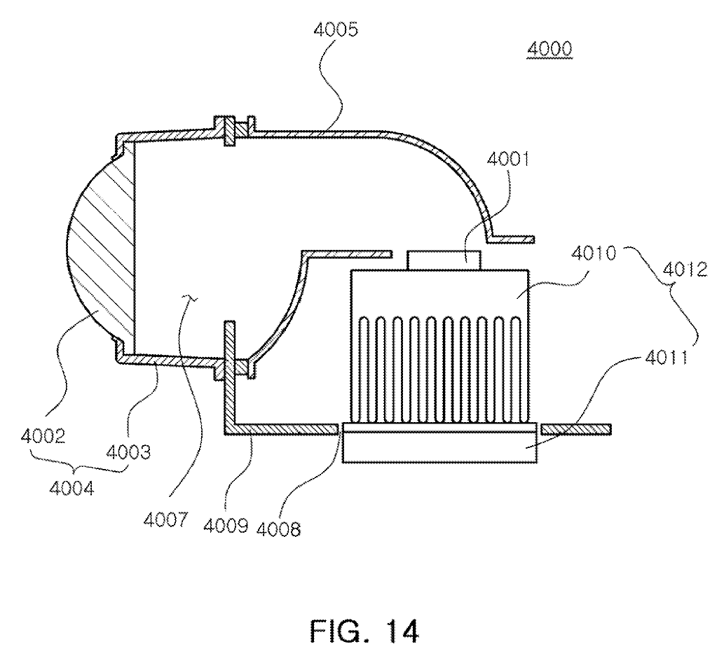

FIG. 14 illustrates an example of a headlamp to which a semiconductor light emitting device package according to an embodiment of the present inventive concept is applied.

With reference to FIG. 14, a headlamp 4000 used in a vehicle or the like may include a light source 4001, a reflective unit 4005 and a lens cover unit 4004, the lens cover unit 4004 including a hollow guide part 4003 and a lens 4002. The light source 4001 may include at least one semiconductor light emitting device package having the above-described structure or a structure similar thereto.

The headlamp 4000 may further include a heat radiating unit 4012 dissipating heat generated in the light source 4001 outwardly. The heat radiating unit 4012 may include a heat sink 4010 and a cooling fan 4011 in order to effectively dissipate heat. In addition, the headlamp 4000 may further include a housing 4009 allowing the heat radiating unit 4012 and the reflective unit 4005 to be fixed thereto and supporting them. One surface of the housing 4009 may be provided with a central hole 4008 into which the heat radiating unit 4012 is inserted to be coupled thereto.

The other surface of the housing 4009 bent in a direction perpendicular to one surface of the housing 4009 may be provided with a forwardly open hole 4007 such that light generated in the light source 4001 may be reflected by the reflective unit 4005 disposed above the light source 4001, pass through the forwardly open hole 4007, and be emitted outwardly.

As set forth above, in a method of manufacturing a semiconductor light emitting device package according to embodiments of the inventive concept, existing processes may be partially omitted or may be simplified, whereby manufacturing yield may be significantly increased. In addition, the manufactured semiconductor light emitting device package may have improved optical and reflective characteristics by replacing an existing Si support structure having a low level of reflectivity with an inventive support structure.

While the present inventive concept has been shown and described in connection with the embodiments, it will be apparent to those skilled in the art that modifications and variations can be made without departing from the spirit and scope of the inventive concept as defined by the appended claims.

What is claimed is:

1. A method of manufacturing a semiconductor light emitting device package, the method comprising:
providing a wafer, on which a semiconductor laminate is formed, wherein the semiconductor laminate comprises a plurality of light emitting devices and electrodes are disposed on respective light emitting device regions of the semiconductor laminate;
providing a semi-cured resin body for a support structure having connection electrodes formed by penetrating through regions of the semi-cured resin body corresponding to the electrodes;
bonding the semi-cured resin body to the semiconductor laminate while allowing the connection electrodes to be connected to the electrodes of the light emitting devices, respectively; and
forming a support structure by fully curing the semi-cured resin body.

2. The method of claim 1, wherein the semi-cured resin body includes a high reflective powder.

3. The method of claim 2, wherein the providing of the semi-cured resin body includes:
forming a body for the support structure using a curable liquid resin; and
forming the semi-cured resin body by curing the body for the support structure so as to be in a B-stage state.

4. The method of claim 3, wherein the providing of the semi-cured resin body includes:
forming through holes in the regions of the semi-cured resin body corresponding to the electrodes; and
forming the connection electrodes in the through holes.

5. The method of claim 1, wherein the connection electrodes formed in the semi-cured resin body have bonding metal layers disposed in regions thereof connected to the electrodes.

6. The method of claim 1, the bonding of the semi-cured resin body to the semiconductor laminate is performed by heating and compressing the semi-cured resin body and the semiconductor laminate.

7. A method of manufacturing a semiconductor light emitting device package, the method comprising:
providing a wafer;
forming, on the wafer, a semiconductor laminate comprising a plurality of light emitting devices;
mesa-etching a portion of the semiconductor laminate;
forming electrodes on the mesa-etched portion of the semiconductor laminate;
applying a curable resin to a surface of the semiconductor laminate on which the electrodes are formed;
forming a support structure for supporting the semiconductor laminate by curing the curable resin;
forming through holes in the support structure to expose the electrodes therethrough; and
forming connection electrodes in the support structure to be connected to the exposed electrodes.

8. The method of claim 7, wherein the curable resin includes a reflective powder.

9. The method of claim 8, wherein the reflective powder includes at least one selected from the group consisting of TiO₂, Al₂O₃, Nb₂O₅, Al₂O₃ and ZnO.

10. The method of claim 7, wherein the curable resin applied to the surface of the semiconductor laminate is a curable liquid resin.

11. The method of claim 7, wherein the surface of the semiconductor laminate on which the electrodes are formed has a step portion.
